(19) United States
(12) Patent Application Publication
(10) Pub. No.: US 2025/0072093 A1
(43) Pub. Date: Feb. 27, 2025

(54) DISPLAY PANEL

(71) Applicant: WUHAN CHINA STAR OPTOELECTRONICS TECHNOLOGY CO., LTD., Wuhan (CN)

(72) Inventors: Zhifu LI, Wuhan (CN); Guanghui LIU, Wuhan (CN); Fei AI, Wuhan (CN); Dewei SONG, Wuhan (CN); Zhuang LI, Wuhan (CN)

(21) Appl. No.: 17/925,002

(22) PCT Filed: Nov. 7, 2022
(86) PCT No.: PCT/CN2022/130324

§ 371 Date: Nov. 19, 2024

(30) Foreign Application Priority Data
Sep. 23, 2022 (CN) 202211167619.2

(51) Int. Cl. H01L 29/45; H01L 29/49; H01L 29/786

(52) U.S. Cl. CPC H01L 29/45; H01L 29/4908; H01L 29/78696

(57) ABSTRACT

A display panel is provided. The display panel includes a substrate and includes a first ohmic contact structure, a first boss, a second ohmic contact structure, a semiconductor structure, and a gate which are stacked on the substrate. The first boss includes at least one sidewall. By arranging the semiconductor structure on the sidewall of the first boss, a length of a channel can be shortened by using an existing technology, and a dimension of a thin film transistor can be reduced, so that an integration level of the thin film transistor in the display panel can be improved.

### FIELD OF DISCLOSURE

The present disclosure relates to the field of display technologies, in particular to a display panel.

### BACKGROUND

Integrating a pixel drive circuit, a gate drive circuit, a source drive circuit, a timing controller, and other circuits on a glass substrate (system on glass, SOG) can greatly improve an integration level of a display panel, reduce a dependence on integrated circuit chips, and reduce costs.

### SUMMARY OF DISCLOSURE

### Technical Problem

A realization of SOG needs to improve an integration level, a maximum operating frequency, and a current density of thin-film transistors in existing display panels, which all require thin-film transistors to have shorter channel lengths, higher mobility, and smaller dimensions.

To sum up, the existing display panel has a problem that an existing technology cannot reduce the channel length and dimension of the thin film transistor. Therefore, it is necessary to provide a display panel to improve this defect.

### Solutions to Problems

### Technical Solutions

Embodiments of the present disclosure provide a display panel, which can reduce a channel length of a thin film transistor and a dimension of the thin film transistor by using an existing technology, increase an on-state current of the thin film transistor, and improve an integration level of the thin film transistor in the display panel.

An embodiment of the present disclosure provides a display panel, including:
a substrate;
a first ohmic contact structure disposed on the substrate;
a first boss disposed on a side of the first ohmic contact structure away from the substrate, the first boss including at least one sidewall;
a second ohmic contact structure disposed on a side of the first boss away from the first ohmic contact structure;
a semiconductor structure disposed at least on the sidewall and in contact with the first ohmic contact structure and the second ohmic contact structure; and
a gate disposed on a side of the semiconductor structure away from the substrate.

According to an embodiment of the present disclosure, the first ohmic contact structure includes a first sidewall adjacent to the sidewall, and the semiconductor structure is in contact with the first sidewall.

According to an embodiment of the present disclosure, the first ohmic contact structure includes:
a body section disposed between the first boss and the substrate; and
a protruding section connected to the body section, where an orthographic projection of the protruding section on the substrate does not overlap with an orthographic projection of the first boss on the substrate, and the semiconductor structure is in contact with a surface of the protruding section away from the substrate.

According to an embodiment of the present disclosure, a length of the protruding section ranges from 0.5 micrometers to 3 micrometers.

According to an embodiment of the present disclosure, the semiconductor structure includes:
a first section disposed on the substrate and/or the first ohmic contact structure;
a second section disposed on the sidewall and connected to the first section; and
a third section disposed on a side of the second ohmic contact structure away from the first boss, and connected to the second section.

According to an embodiment of the present disclosure, an included angle between the sidewall and a plane where the substrate is located ranges from 45 degrees to 90 degrees.

According to an embodiment of the present disclosure, the first boss includes two sidewalls disposed opposite to each other, and the semiconductor structure and the gate disposed on the side of the semiconductor structure away from the substrate are arranged on the two sidewalls.

The semiconductor structure on the two sidewalls is in contact with the first ohmic contact structure and the second ohmic contact structure.

According to an embodiment of the present disclosure, the semiconductor structure is continuously disposed on the two sidewalls of the first boss and the second ohmic contact structure.

According to an embodiment of the present disclosure, an orthographic projection of the gate on the substrate covers an orthographic projection of the semiconductor structure on the substrate.

According to an embodiment of the present disclosure, the display panel includes:
a third ohmic contact structure disposed on the substrate;
a second boss disposed on a side of the third ohmic contact structure away from the substrate; and
a fourth ohmic contact structure disposed on a side of the second boss away from the first ohmic contact structure, where the semiconductor structure is arranged at least on a sidewall of the second boss, and is in contact with the third ohmic contact structure and the fourth ohmic contact structure.

The display panel further includes a source and a drain, one of the source and the drain is electrically connected to the first ohmic contact structure and the third ohmic contact structure, and another one of the source and the drain is electrically connected to the second ohmic contact structure and the fourth ohmic contact structure.

According to an embodiment of the present disclosure, the semiconductor structure is continuously disposed on the first boss, the second boss, and a region between the first boss and the second boss.

According to an embodiment of the present disclosure, an orthographic projection of the gate on the substrate covers an orthographic projection of the semiconductor structure on the substrate.

According to an embodiment of the present disclosure, the display panel further includes a gate insulating layer and an interlayer dielectric layer, the gate insulating layer is disposed at least between the gate and the semiconductor structure and covers the second ohmic contact structure and the first ohmic contact structure, the interlayer dielectric layer is disposed on a side of the gate insulating layer away from the substrate and covers the gate;
the display panel further includes a source and a drain, the source and the drain are both disposed on a side of the interlayer dielectric layer away from the substrate, one of the source and the drain is in contact with the first ohmic contact structure through the interlayer dielectric layer and the gate insulating layer, and another one of the source and the drain is in contact with the second ohmic contact structure through the interlayer dielectric layer and the gate insulating layer.

According to an embodiment of the present disclosure, the display panel further includes a light-shielding structure, the light-shielding structure is disposed on a side of the first ohmic contact structure close to the substrate, and the semiconductor structure includes a channel portion connected to the first ohmic contact structure and the second ohmic contact structure.

An orthographic projection of the light-shielding structure on the substrate covers an orthographic projection of the channel portion on the substrate.

According to an embodiment of the present disclosure, a length of the channel portion along an extending direction of the sidewall ranges from 0.01 micrometer to 1 micrometer.

According to an embodiment of the present disclosure, a thickness of the first boss in a thickness direction of the display panel ranges from 0.0071 micrometers to 1 micrometer.

According to an embodiment of the present disclosure, the first boss is a single-layer or multi-layer structure.

According to an embodiment of the present disclosure, material of the first boss includes one or a combination of silicon nitride, silicon oxide, and silicon oxynitride.

According to an embodiment of the present disclosure, material of the first boss includes one or a combination of acrylic based resin, epoxy resin, phenolic resin, polyamide based resin, polyimide based resin, unsaturated polyester resin, polyacrylate, polycarbonate, polyimide, polystyrene.

According to an embodiment of the present disclosure, the sidewall includes a flat surface or an arc surface.

### Beneficial Effect of Invention

### Beneficial Effect

Advantages of the embodiments of the present disclosure are as follows. Embodiments of the present disclosure provide a display panel. The display panel includes a substrate and includes a first ohmic contact structure, a second ohmic contact structure, a semiconductor structure, and a gate which are stacked on the substrate. The first boss includes at least one sidewall. The semiconductor structure is disposed on the sidewall of the first boss, and is in contact with the first ohmic contact structure and the second ohmic contact structure. A channel length of a thin film transistor can be shortened by using an existing technology, and a dimension of the thin film transistor can be reduced, so that an integration level of the thin film transistor in the display panel can be improved.

### BRIEF DESCRIPTION OF DRAWINGS

### Description of Drawings

In order to illustrate technical solutions in the embodiments or the prior art more clearly, the following briefly introduces the accompanying drawings that are required to be used in the description of the embodiments or the prior art. Apparently, the drawings in the following description are only some of the disclosed embodiments. For those of ordinary skill in the art, other drawings can also be obtained from these drawings without creative efforts.

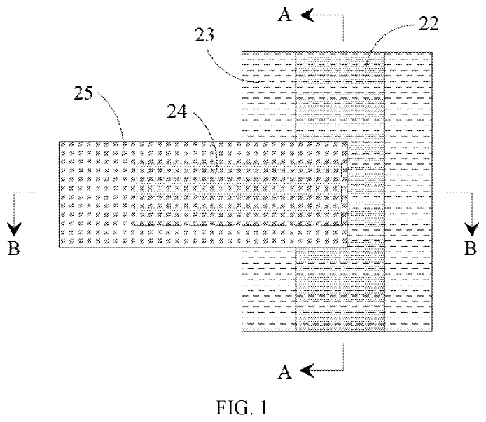

FIG. 1 is a schematic plan view of a first type of thin film transistor of an embodiment of the present disclosure.

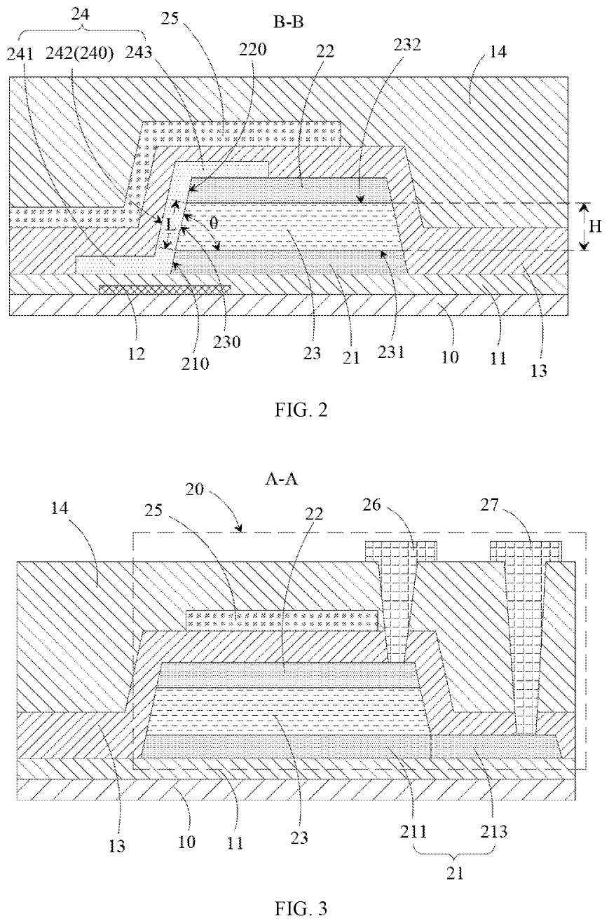

FIG. 2 is a schematic cross-sectional view of the first type of thin film transistor along a B-B direction of an embodiment of the present disclosure.

FIG. 3 is a schematic cross-sectional view of the first type of thin film transistor along an A-A direction of an embodiment of the present disclosure.

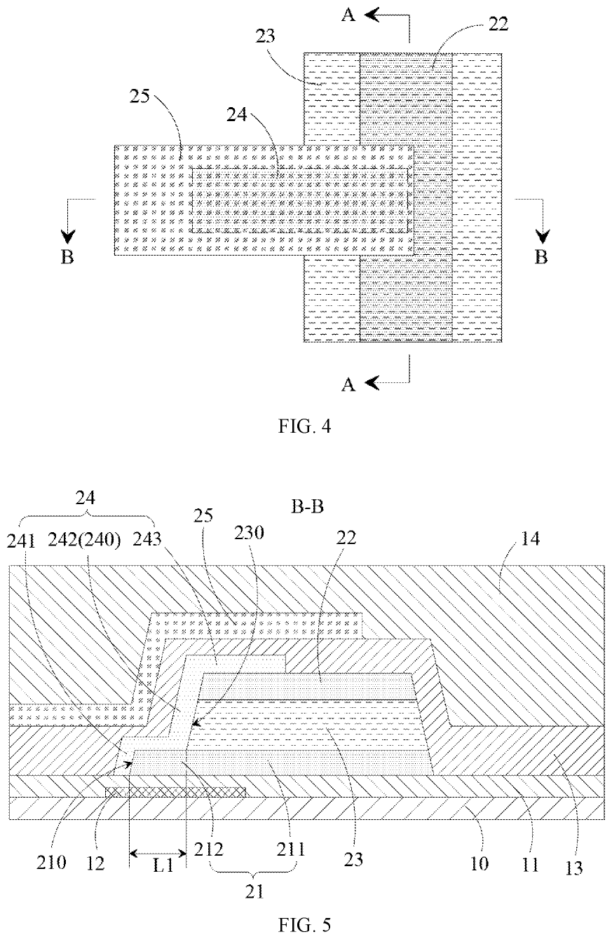

FIG. 4 is a schematic plan view of a second type of thin film transistor of an embodiment of the present disclosure.

FIG. 5 is a schematic cross-sectional view of the second type of thin film transistor along a B-B direction of an embodiment of the present disclosure.

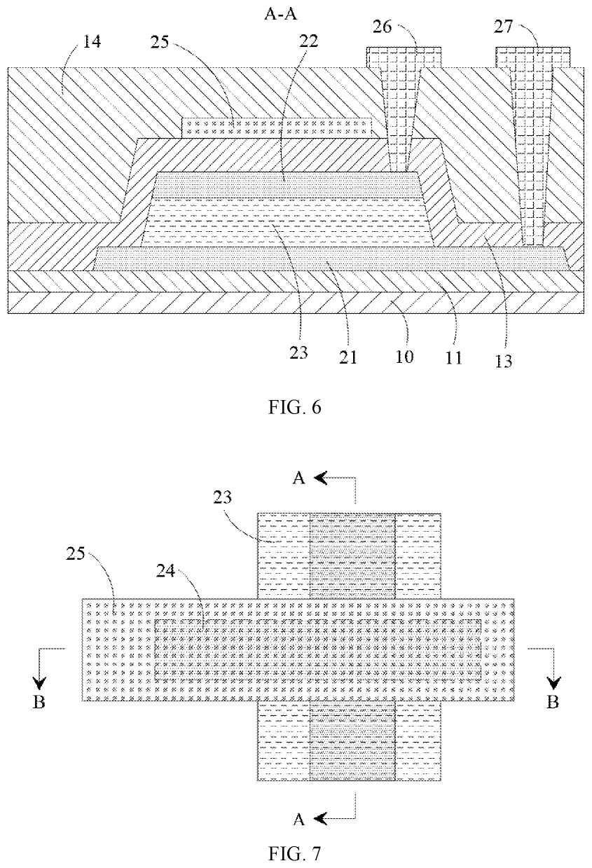

FIG. 6 is a schematic cross-sectional view of the second type of thin film transistor along an A-A direction of an embodiment of the present disclosure.

FIG. 7 is a schematic plan view of a third type of thin film transistor of an embodiment of the present disclosure.

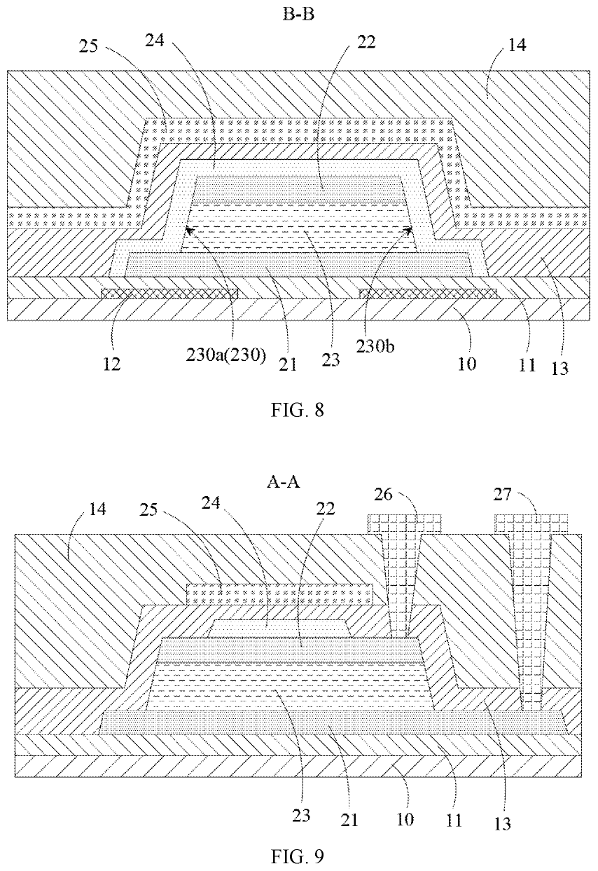

FIG. 8 is a schematic cross-sectional view of the third type of thin film transistor along a B-B direction of an embodiment of the present disclosure.

FIG. 9 is a schematic cross-sectional view of the third type of thin film transistor along an A-A direction of an embodiment of the present disclosure.

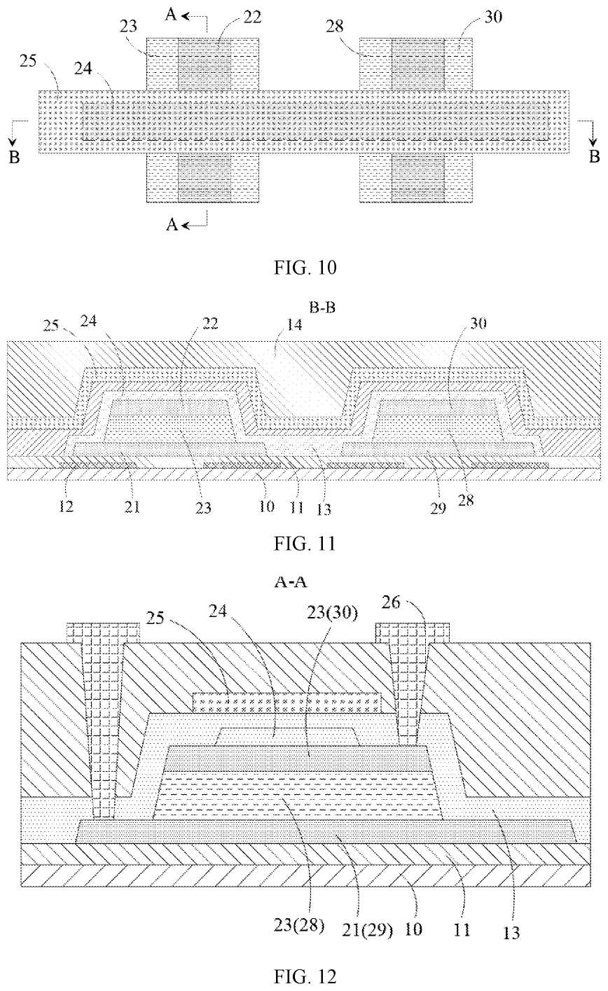

FIG. 10 is a schematic plan view of a fourth type of thin film transistor of an embodiment of the present disclosure.

FIG. 11 is a schematic cross-sectional view of the fourth type of thin film transistor along a B-B direction of an embodiment of the present disclosure.

FIG. 12 is a schematic cross-sectional view of the fourth type of thin film transistor along an A-A direction of an embodiment of the present disclosure.

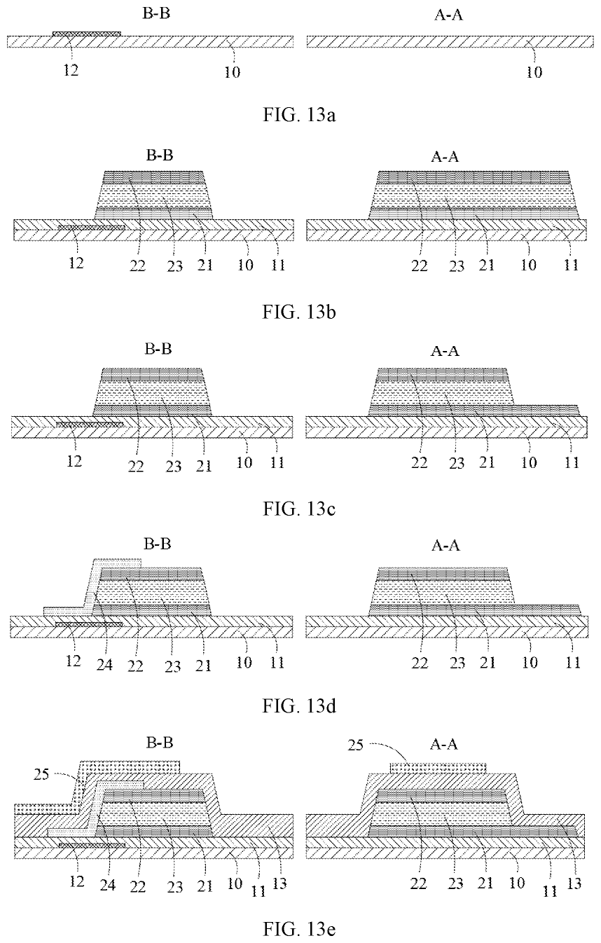

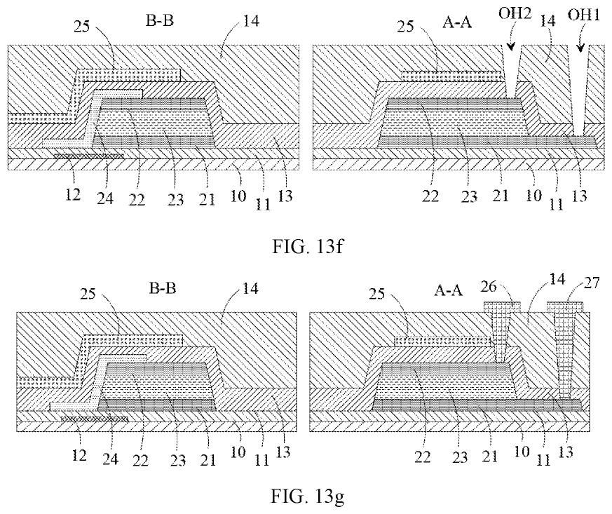

FIG. 13a to FIG. 13g are schematic diagrams illustrating a flow of a manufacturing method of a display panel of an embodiment of the present disclosure.

### EMBODIMENTS OF THE INVENTION

### Detailed Description of Preferred Embodiments

The following descriptions of the various embodiments refer to the accompanying drawings to illustrate specific embodiments in which the present disclosure may be practiced. The directional terms mentioned in the present disclosure, such as up, down, front, rear, left, right, inner, outer, side, etc., are only the orientations with reference to the accompanying drawings. Accordingly, the directional terms used are intended to illustrate and understand the present disclosure, not to limit the present disclosure. In the figures, structurally similar elements are denoted by the same reference numerals.

The present disclosure is further described below in conjunction with the accompanying drawings and specific embodiments.

The embodiments of the present disclosure provide a display panel, which can reduce a channel length of a thin film transistor and a dimension of the thin film transistor by using the existing technology, increase an on-state current of the thin film transistor, and improve an integration level of the thin film transistor in the display panel.

The display panel includes a substrate 10 and a plurality of thin film transistors 20 disposed on the substrate 10. The thin film transistor 20 can be applied to at least one circuit module of the display panel, such as a pixel driving circuit, a gate driving circuit, a source driving circuit, a timing controller, and the like.

It should be noted that, being disposed on the substrate 10 may refer to direct contact with the substrate 10, or may refer to indirect contact with the substrate 10.

Referring to FIG. 1 to FIG. 3, FIG. 1 is a schematic plan view of a first type of thin film transistor of an embodiment of the present disclosure, FIG. 2 is a schematic cross-sectional view of the first type of thin film transistor along a B-B direction of an embodiment of the present disclosure, and FIG. 3 is a schematic cross-sectional view of the first type of thin film transistor along an A-A direction of an embodiment of the present disclosure. The display panel may further include a buffer layer 11, the buffer layer 11 is disposed on a surface of the substrate 10 close to a thin film transistor 20, and the thin film transistor 20 is disposed on the buffer layer 11.

Furthermore, the display panel includes a first ohmic contact structure 21, a first boss 23, a second ohmic contact structure 22, a semiconductor structure 24, and a gate 25.

The first ohmic contact structure 21 is disposed on the substrate 10. For example, the first ohmic contact structure 21 may be disposed on a surface of the buffer layer 11 away from the substrate 10.

Material of the first ohmic contact structure 21 is N-type heavily doped amorphous silicon material, and the first ohmic contact structure 21 may be doped with element impurities such as phosphorus or arsenic.

The first boss 23 is disposed on a side of the first ohmic contact structure 21 away from the substrate 10.

Material of the first boss 23 may be a single-layer or multi-layer structure formed of an inorganic insulating material or an organic insulating material. If the first boss 23 is a multi-layer structure, the first boss 23 may be a stacked structure formed by stacking multiple layers of the same material in sequence, or may be formed by stacking at least two different materials.

For example, the material of the first boss 23 may be a common inorganic insulating material such as silicon nitride, silicon oxide, or silicon oxynitride. The material of the first boss 23 may also be any one or a combination of two or more materials of acrylic-based resins, epoxy resins, phenolic resins, polyamide-based resins, polyimide-based resins, unsaturated polyester resins, polyacrylates, polycarbonates, polyimides, polystyrenes.

The second ohmic contact structure 22 is disposed on a side of the first boss 23 away from the first ohmic contact structure 21.

Material of the second ohmic contact structure 22 is N-type heavily doped amorphous silicon material, and the second ohmic contact structure 22 may be doped with element impurities such as phosphorus or arsenic.

Furthermore, the first boss 23 includes at least one sidewall 230. The semiconductor structure 24 is disposed on at least the sidewall 230 and is in contact with the first ohmic contact structure 21 and the second ohmic contact structure 22.

In one of the embodiments, the first boss 23 may include a first surface 231 and a second surface 232 disposed opposite to each other. The first surface 231 and the second surface 232 may be arranged parallel to each other. The second surface 232 may be disposed on a side of the first surface 231 away from the substrate 10.

The first surface 231 may be in direct contact with a surface of the first ohmic contact structure 21 away from the substrate 10. The second ohmic contact structure 22 may be disposed on a side of the second surface 232 away from the substrate 10 and may be in direct contact with the second surface 232.

The sidewall 230 is disposed between the first surface 231 and the second surface 232, and is connected to the first surface 231 and the second surface 232. The sidewall 230 is arranged in an inclined state, and there are certain included angles between the sidewall 230 and the first surface 231 and the second surface 232.

The semiconductor structure 24 is disposed along the sidewall 230 and extends to contact the first ohmic contact structure 21 and the second ohmic contact structure 22.

Material of the semiconductor structure 24 is undoped polysilicon material. A channel portion 240 in the semiconductor structure 24 which is disposed opposite to the sidewall 230 may serve as a channel of the thin film transistor 20. A length L of the channel portion 240 along an extending direction of the sidewall 230 is a channel length of the thin film transistor.

The gate 25 is disposed on a side of the semiconductor structure 24 away from the substrate 10.

As shown in FIG. 2, the display panel further includes a gate insulating layer 13. The gate insulating layer 13 is disposed on a side of the semiconductor structure 24 away from the substrate 10 and continuously covers the semiconductor structure 24, the second ohmic contact structure 22, the first boss 23, the first ohmic contact structure 21, and the buffer layer 11.

At the first boss 23, a portion of the gate insulating layer 13 is arranged on the buffer layer 11 and the horizontally arranged semiconductor structure 24 in a tiled manner. Another portion of the gate insulating layer 13 extends along a portion of the semiconductor structure 24 on the sidewall 230 and is also in the inclined state. Another portion of the gate insulating layer 13 extends to a surface of the second ohmic contact structure 22 away from the first boss 23 and covers the semiconductor structure 24 located above the second surface 232 of the first boss 23.

A portion of the gate 25 is arranged on the horizontally arranged gate insulating layer 13 in a tiled manner. Another portion of the gate 25 is disposed on the gate insulating layer 13 in the inclined state, and is also in the inclined state. Another portion of the gate 25 extends to a surface of the gate insulating layer 13 away from the second ohmic contact structure 22.

An orthographic projection of the gate 25 on the sidewall 230 can cover an orthographic projection of the channel portion 240 on the sidewall 230, so that the gate 25 can control the channel portion 240.

In one embodiment, the first ohmic contact structure 21 includes a first sidewall 210 adjacent to the sidewall 230, and the semiconductor structure 24 is in contact with the first sidewall 210.

As shown in FIG. 2, a surface of the first ohmic contact structure 21 close to the first boss 23 completely overlaps with the first surface 231 of the first boss 23. One end of the first ohmic contact structure 21 close to the semiconductor structure 24 has an inclined first sidewall 210. The first sidewall 210 is adjacent to the sidewall 230 of the first boss 23. The semiconductor structure 24 is in contact with the first sidewall 210.

In one embodiment, both the first sidewall 210 and the sidewall 230 are flat surfaces. An included angle between the first sidewall 210 and a plane where the substrate 10 is located may be the same as an included angle between the sidewall 230 of the first boss 23 and the plane where the substrate 10 is located. That is, the first sidewall 210 and the sidewall 230 are arranged on a same inclined plane.

In one of the embodiments, the sidewall 230 may also be an arc surface, a non-planar surface with multiple protrusions or recesses, or other special-shaped surfaces. The arc surface may be an arc surface concave inward of the first boss 23 or an arc surface protruding outward, which is not limited here.

Furthermore, the semiconductor structure 24 is configured to extend along the sidewall 230 to a surface of the second ohmic contact structure 22 away from the first boss 23.

As shown in FIG. 2, a surface of the second ohmic contact structure 22 close to the first boss 23 completely overlaps with the second surface 232 of the first boss 23. One end of the second ohmic contact structure 22 close to the semiconductor structure 24 has an inclined second sidewall 220. The second sidewall 220 is adjacent to the sidewall 230 of the first boss 23. The semiconductor structure 24 may be in contact with the second sidewall 220 and extend along the second sidewall 220 to a surface of the second ohmic contact structure 22 away from the first boss 23.

In one of the embodiments, the semiconductor structure 24 may include a first section 241, a second section 242, and a third section 243. The first section 241 may be disposed on the substrate 10 and/or the first ohmic contact structure 21. The second section 242 may be arranged on the sidewall 230. The third section 243 may be disposed on a surface of the second ohmic contact structure 22 away from the first boss 23.

As shown in FIG. 2, the first section 241 may be arranged on a surface of the buffer layer 11 away from the substrate 10 in a tiled manner. When the buffer layer 11 is not provided, the first section 241 can be directly disposed on the substrate 10 in a tiled manner. The second section 242 is not only disposed on the sidewall 230, but also can be disposed on the first sidewall 210 and the second sidewall 220 to be in contact with the first ohmic contact structure 21 and the second ohmic contact structure 22. The third section 243 may be arranged on a surface of the second ohmic contact structure 22 away from the first boss 23 in a tiled manner.

It should be noted that by extending an arrangement range of the semiconductor structure 24 in the B-B direction, it extends to the buffer layer 11 on the side of the first ohmic contact structure 21 and the surface of the second ohmic contact structure 22 away from the substrate 10. It is easier to implement in the existing process, and precision requirements for an exposure machine can be reduced.

In one of the embodiments, the semiconductor structure 24 may have only the second section 242. That is, the semiconductor structure 24 may be disposed only on the first sidewall 210, the sidewall 230, and the second sidewall 220.

The first section 241 and the third section 243 may be arranged parallel to each other, and there is a certain included angle between the first section 241 and the second section 242.

When amorphous silicon in the semiconductor structure 24 is subjected to a crystallization process by an excimer laser annealing (ELA) process, a seed crystal may be formed at a corner of the first section 241 and the second section 242. The seed crystal may grow along the sidewall 230 of the first boss 23. By controlling a length of the sidewall 230 between 0.01 micrometers and 1 micrometer, a channel length L of the thin film transistor can be controlled between 0.01 micrometers and 1 micrometer. In this way, only one crystal grain can exist in the channel portion 240 of the semiconductor structure 24.

Compared with an existing low temperature polysilicon thin film transistor in which an entire active layer is on a same plane, a channel length is generally more than 2 micrometers due to limitations of exposure and etching processes. Moreover, there are many grain boundaries in the channel, and a mobility of the thin film transistor is low. In an embodiment of the present disclosure, the channel (i.e., the channel portion 240 of the semiconductor structure 24) of the thin film transistor is formed on the sidewall 230 of the first boss 23. The channel length of the thin film transistor can be shortened to between 0.01 micrometers and 1 micrometer by using the existing technology. Also, the channel is composed of a single crystal grain, and there is no grain boundary, so that a size of the thin film transistor can be reduced, and a mobility of the thin film transistor can be greatly improved.

Furthermore, an included angle θ between the sidewall 230 and a plane where the substrate 10 is located ranges from 45 degrees to 90 degrees.

For example, the included angle θ between the sidewall 230 and the plane where the substrate 10 is located may be 45 degrees, 60 degrees, 75 degrees, 80 degrees, or 90 degrees, etc., so that a corner can be formed between the sidewall 230 of the first boss 23 and the plane where the substrate 10 or the buffer layer 11 is located, and it is ensured that during the ELA process, a seed crystal grown along the sidewall 230 can be formed at the corner of the first section 241 and the second section 242.

Furthermore, a thickness H of the first boss 23 in a thickness direction of the display panel ranges from 0.0071 micrometers to 1 micrometer.

It should be noted that the channel length L of the thin film transistor 20 is equal to the length of the sidewall 230 of the first boss 23. The channel length L of the thin film transistor 20 depends on the thickness H of the first boss 23 along the thickness direction of the display panel and the included angle θ between the sidewall 230 and the plane where the substrate 10 is located, that is, L=H/sin θ. By limiting the thickness H of the first boss 23 to be between 0.0071 micrometers and 1 micrometer, and limiting the included angle θ between the sidewall 230 and the plane where the substrate 10 is located to be between 45 degrees and 90 degrees, the channel length L of the thin film transistor can be set to be between 0.01 micrometers and 1 micrometer, so as to ensure that only one crystal grain exists in the channel of the thin film transistor.

Furthermore, the display panel further includes an interlayer dielectric layer 14, a source 26, and a drain 27. The interlayer dielectric layer 14 is disposed on a side of the gate insulating layer 13 away from the substrate 10 and covers the gate 25.

The source 26 and the drain 27 are both disposed on a side of the interlayer dielectric layer 14 away from the substrate 10. One of the source 26 and the drain 27 is electrically connected to the first ohmic contact structure 21. Another one of the source 26 and the drain 27 is electrically connected to the second ohmic contact structure 22. The thin film transistor 20 may be composed of, but not limited to, the source 26, the drain 27, the first ohmic contact structure 21, the second ohmic contact structure 22, the semiconductor structure 24, and the gate 25.

As shown in FIG. 3, the first ohmic contact structure 21 includes a body section 211 and an overlapping section 213. The body section 211 is disposed between the first boss 23 and the substrate 10. The overlapping section 213 is connected to the body section 211. An orthographic projection of the overlapping section 213 on the substrate 10 does not overlap with an orthographic projection of the first boss 23 on the substrate 10.

The overlapping section 213 and the body section 211 are portions of the first ohmic contact structure 21. The overlapping section 213 can be regarded as a portion of one side edge of the first ohmic contact structure 21 extending in the A-A direction from the body section 211 and beyond the first boss 23. The drain 27 is in contact with a surface of the overlapping section 213 away from the substrate 10 through the interlayer dielectric layer 14 and the gate insulating layer 13. The source 26 is in contact with a surface of the second ohmic contact structure 22 away from the substrate 10 through the interlayer dielectric layer 14 and the gate insulating layer 13.

Referring to FIG. 4 to FIG. 6, FIG. 4 is a schematic plan view of a second type of thin film transistor of an embodiment of the present disclosure, FIG. 5 is a schematic cross-sectional view of the second type of thin film transistor along a B-B direction of an embodiment of the present disclosure, and FIG. 6 is a schematic cross-sectional view of the second type of thin film transistor along an A-A direction of an embodiment of the present disclosure. A structure of the second type of display panel shown in FIG. 4 to FIG. 6 is roughly the same as that of the first type of display panel shown in FIG. 1 to FIG. 3, the differences are that: the first ohmic contact structure 21 includes a body section 211 and a protruding section 212, the body section 211 is arranged between the first boss 23 and the substrate 10, the protruding section 212 is connected to the body section 211, and an orthographic projection of the protruding section 212 on the substrate 10 does not overlap with an orthographic projection of the first boss 23 on the substrate 10.

It should be noted that the protruding section 212 and the body section 211 are portion of the first ohmic contact structure 21. The protruding section 212 can be regarded as a portion of an edge of the first ohmic contact structure 21 extending from one end of the body section 211 and beyond the first boss 23. The semiconductor structure 24 is in contact with a surface of the protruding section 212 away from the substrate 10.

In the embodiment shown in FIG. 2, the semiconductor structure 24 is in contact with the first sidewall 210 of the first ohmic contact structure 21, and a contact area is relatively small. In the embodiment shown in FIG. 4, the semiconductor structure 24 is in contact with the surface of the protruding section 212 of the first ohmic contact structure 21 that extends beyond the edge of the first boss 23 away from the substrate 10, and a contact area is relatively large. In this way, by increasing the contact area between the semiconductor structure 24 and the first ohmic contact structure 21, a risk of poor contact between the semiconductor structure 24 and the first ohmic contact structure 21 is reduced.

In one embodiment, the first section 241 of the semiconductor structure 24 may be disposed on the substrate 10 and the first ohmic contact structure 21.

It should be noted that, being disposed on the substrate 10 may refer to direct contact with the substrate 10, or may refer to indirect contact with the substrate 10.

As shown in FIG. 2, the first section 241 of the semiconductor structure 24 is disposed on a surface of the buffer layer 11 away from the substrate 10 and on a surface of the protruding section 212 away from the substrate 10. The semiconductor structure 24 can be in contact with a surface of the protruding section 212 away from the substrate 10 and the first sidewall 210 of the protruding section 212 at the same time. In this way, the contact area between the semiconductor structure 24 and the first ohmic contact structure 21 can be further increased.

In one embodiment, the first section 241 of the semiconductor structure 24 may also be disposed only on a surface of the protruding section 212 of the first ohmic contact structure 21 away from the substrate 10. In this way, the contact area with the first ohmic contact structure 21 can also be increased.

Furthermore, a length L1 of the protruding section 212 ranges from 0.5 micrometers and 3 micrometers. For example, the length L1 of the protruding section 212 may be 0.5 micrometers, 0.8 micrometers, 1 micrometer, 1.5 micrometers, 2 micrometers, 2.5 micrometers, or 3 micrometers. In this way, a corner can be formed between the protruding section 212 and the sidewall 230 of the first boss 23. Also, the semiconductor structure 24 can form a seed crystal growing along the sidewall 230 at the corner of the protruding section 212 and the sidewall 230, so as to ensure that there is only one crystal grain in the channel of the thin film transistor.

Referring to FIG. 7 to FIG. 9, FIG. 7 is a schematic plan view of a third type of thin film transistor of an embodiment of the present disclosure, FIG. 8 is a schematic cross-sectional view of the third type of thin film transistor along a B-B direction of an embodiment of the present disclosure, and FIG. 9 is a schematic cross-sectional view of the third type of thin film transistor along an A-A direction of an embodiment of the present disclosure. A structure of the third type of display panel shown in FIG. 7 to FIG. 9 is roughly the same as that of the second type of display panel shown in FIG. 4 to FIG. 6, the differences are that: the first boss 23 includes two sidewalls 230 disposed opposite to each other, and the semiconductor structure 24 and the gate 25 disposed on the side of the semiconductor structure 24 away from the substrate 10 are disposed on the two sidewalls 230.

As shown in FIG. 8, the first boss 23 includes two sidewalls 230a and 230b arranged opposite to each other. The semiconductor structure 24 is disposed on both the sidewall 230a and the sidewall 230b. The semiconductor structure 24 on the sidewall 230a and the sidewall 230b is in contact with the first ohmic contact structure 21 and the second ohmic contact structure 22.

The gate 25 is disposed on the side of the semiconductor structure 24 on the sidewall 230a away from the substrate 10. The gate 25 is also disposed on the side of the semiconductor structure 24 on the sidewall 230b away from the substrate 10. The semiconductor structure 24 on the sidewall 230a and the sidewall 230b can be controlled through the two portions of the gate on both sides of the first boss 23. This is equivalent to connecting channels of the semiconductor structures 24 on both sides of the first boss 23 in parallel, thereby increasing an equivalent channel width of the thin film transistor, and increasing an on-state current of the thin film transistor. For a pixel driving circuit of a liquid crystal display panel, a charging time of a pixel capacitor can be reduced, which is beneficial to improve a refresh rate of the display panel.

In one embodiment, the semiconductor structure 24 is continuously arranged on the two sidewalls 230 of the first boss 23 and the second ohmic contact structure 22.

Referring to FIG. 7 and FIG. 8, the semiconductor structure 24 is configured to extend from one side of the first boss 23, passing through the sidewall 230 a and a surface of the second ohmic contact structure 22 away from the first boss 23 in sequence, and to the sidewall 230b on the other side of the first boss 23.

Furthermore, the gate 25 is continuously arranged on the semiconductor structure 24 on the two sidewalls 230 of the first boss 23 and on the semiconductor structure 24 on the side of the second ohmic contact structure 22 away from the substrate 10.

Referring to FIG. 7 and FIG. 8, the gate 25 is configured to extend from one side of the first boss 23, passing through the sidewall 230a and a surface of the second ohmic contact structure 22 away from the first boss 23 in sequence, and to the sidewall 230b on the other side of the first boss 23. An orthographic projection of the gate 25 on the substrate 10 may cover an orthographic projection of the semiconductor structure 24 on the substrate 10. From a perspective of thin film transistor arrays, by connecting the gates 25 on the opposite sides of the first boss 23 together, the gates on the opposite sides of each of the first bosses 23 can be controlled simultaneously by one uninterrupted scan line, thereby simplifying a patterning complexity of a gate metal layer.

In one embodiment, the semiconductor structures 24 located on both sides of the first boss 23 may also be disconnected from each other and arranged at intervals on a surface of the second ohmic contact structure 22 away from the first boss 23. The gates 25 located on both sides of the first boss 23 may also be disconnected from each other and arranged at intervals on a surface of the second ohmic contact structure 22 away from the first boss 23.

In one of the embodiments, refer to FIG. 10 to FIG. 12, FIG. 10 is a schematic plan view of a fourth type of thin film transistor of an embodiment of the present disclosure, FIG. 11 is a schematic cross-sectional view of the fourth type of thin film transistor along a B-B direction of an embodiment of the present disclosure, and FIG. 12 is a schematic cross-sectional view of the fourth type of thin film transistor along an A-A direction of an embodiment of the present disclosure. A structure of the fourth type of display panel shown in FIG. 10 to FIG. 12 is roughly the same as the structure of the third type of display panel shown in FIG. 7 to FIG. 9, the differences are that: the display panel further includes a second boss 28, a third ohmic contact structure 29, and two of the fourth ohmic contact structures 30, the third ohmic contact structure 29 is disposed on the substrate 10, the second boss 28 is disposed on a side of the third ohmic contact structure 29 away from the substrate 10, and the fourth ohmic contact structure 30 is disposed on a side of the second boss 28 away from the third ohmic contact structure 29.

As shown in FIG. 11, the third ohmic contact structure 29 and the first ohmic contact structure 21 are disposed in a same layer, and both are disposed on a surface of the buffer layer 11 away from the substrate 10. The second boss 28 is disposed on a side of the third ohmic contact structure 29 away from the substrate 10. The fourth ohmic contact structure 30 is disposed on a side of the second boss 28 away from the third ohmic contact structure 29.

The structure of the second boss 28 can refer to the structure of the first boss 23 in the above embodiment, the structure of the semiconductor structure on the boss 28 can also refer to the structure of the corresponding semiconductor structure 24 on the first boss 23 in the above-mentioned embodiment, which are not repeated here.

In one of the embodiments, the structure of the second boss 28 may be the same as that of the first boss 23, with two inclined sidewalls disposed opposite to each other. The semiconductor structure 24 may be disposed at least on the sidewall of the second boss 28 and in contact with the third ohmic contact structure 29 and the fourth ohmic contact structure 30. At the second boss 28, the gate 25 is also disposed on the side of the semiconductor structure 24 away from the substrate 10.

One of the source 26 and the drain 27 is electrically connected to the first ohmic contact structure 21 and the third ohmic contact structure 29. Another one of the source 26 and the drain 27 is electrically connected to the second ohmic contact structure 22 and the fourth ohmic contact structure 30.

For example, in the same thin film transistor, the thin film transistor may include both the first boss 23 and the second boss 28. The source 26 is connected to the first ohmic contact structure 21 and the third ohmic contact structure 29. The drain 27 is connected to the second ohmic contact structure 22 and the fourth ohmic contact structure 30. The first ohmic contact structure 21 and the third ohmic contact structure 29 are connected in parallel through the source 26. The second ohmic contact structure 22 and the fourth ohmic contact structure 30 are connected in parallel through the drain 27. On the basis of the embodiments shown in FIG. 7 to FIG. 9, an equivalent channel width of the thin film transistor can be further increased.

In some other embodiments, the thin film transistor may also include three or more bosses and ohmic contact structures corresponding to upper and lower sides of the bosses. By connecting the channels corresponding to multiple bosses in parallel, the equivalent channel width of the thin film transistor 20 can be further increased. The number of the bosses in the thin film transistor and the number of ohmic contact structures corresponding to the upper and lower sides of the bosses can be selected according to actual requirements, which is not limited here.

In one of the embodiments, the semiconductor structure 24 is continuously arranged on the first boss 23, the second boss 28, and a region between the first boss 23 and the second boss 28.

Referring to FIG. 10 to FIG. 11, the semiconductor structure 24 extends from the side of the first boss 23 away from the second boss 28, passing through the first boss 23 and the region between the first boss 23 and the second boss 28, to the side of the second boss 28 away from the first boss 23.

Furthermore, the gate 25 is continuously arranged on the semiconductor structure 24 corresponding to the first boss 23 and the second boss 28 and on the semiconductor structure 24 between the first boss 23 and the second boss 28.

Referring to FIG. 10 to FIG. 11, the gate 25 extends from the side of the first boss 23 away from the second boss 28, passing through the first boss 23 and the region between the first boss 23 and the second boss 28, to the side of the second boss 28 away from the first boss 23. An orthographic projection of the gate 25 on the substrate 10 may cover an orthographic projection of the semiconductor structure 24 on the substrate 10. From the perspective of thin film transistor arrays, by connecting the gates 25 on the first boss 23 and the second boss 28 together, the gate 25 on the first boss 23 and the second boss 28 can be controlled at the same time by using an uninterrupted scan line, thereby simplifying the patterning complexity of the gate metal layer.

In one embodiment, the semiconductor structure 24 may also be disconnected from each other and arranged at intervals in a region between the first boss 23 and the second boss 28. The gate 25 may also be disconnected from each other and arranged at intervals in a region between the first boss 23 and the second boss 28.

Furthermore, the display panel further includes a gate insulating layer 13 and an interlayer dielectric layer 14. The gate insulating layer 13 is disposed on a side of the semiconductor structure 24 away from the substrate 10, and covers the semiconductor structure 24, the second ohmic contact structure 22, the first boss 23, and the first ohmic contact structure 21. The gate 25 is disposed on a side of the gate insulating layer 13 away from the substrate 10.

The interlayer dielectric layer 14 is disposed on a side of the gate insulating layer 13 away from the substrate 10 and covers the gate 25.

The source 26 and the drain 27 are both disposed on the side of the interlayer dielectric layer 14 away from the substrate 10. One of the source 26 and the drain 27 is in contact with the first ohmic contact structure 21 through the interlayer insulating layer 14 and the gate dielectric layer 13. The other of the source 26 and the drain 27 is in contact with the second ohmic contact structure 22 through the interlayer insulating layer 14 and the gate dielectric layer 13.

In one embodiment, as shown in FIG. 2, the display panel further includes a light-shielding structure 12. The light-shielding structure 12 is disposed on a side of the first ohmic contact structure 21 close to the substrate 10. The semiconductor structure 24 includes a channel portion 240 disposed opposite to the sidewall 230.

An orthographic projection of the light-shielding structure 12 on the substrate 10 covers an orthographic projection of the channel portion 240 on the substrate 10. By shielding the channel portion 240 by the light-shielding structure 12, light can be prevented from being irradiated to the channel portion 240 through one side of the substrate 10, thereby preventing the light from affecting an electrical performance of the thin film transistor 20.

In one embodiment, as shown in FIG. 8 and FIG. 11, when the thin film transistor includes two or more channel portions 240, the corresponding light-shielding structure 12 is disposed under each of the channel portions 240.

According to the display panel provided by the above embodiments of the present disclosure, the embodiments of the present disclosure also provide a manufacturing method of a display panel. Referring to FIG. 13a to FIG. 13g, which are schematic diagrams illustrating a flow of a manufacturing method of a display panel of an embodiment of the present disclosure, and the manufacturing method of the display panel includes:
Step S1, a light-shielding structure 12 is formed on the substrate 10;
Step S2, a buffer layer 11 is formed on the substrate 10, a first ohmic contact layer, an insulating layer, and a second ohmic contact layer are sequentially formed on the buffer layer 11, the first ohmic contact layer, the insulating layer, and the second ohmic contact layer are etched, and a first ohmic contact structure 21, a first boss 23, and a second ohmic contact structure 22 are formed;

In the step S20, material of the buffer layer 11 may include, but is not limited to, any one or a combination of materials of silicon nitride, silicon oxide, or silicon oxynitride.

In the step S20, as shown in FIG. 13b, the first ohmic contact structure 21 is disposed on the buffer layer 11. The first boss 23 is disposed on a side of the first ohmic contact structure 21 away from the buffer layer 11. The second ohmic contact structure 22 is disposed on a side of the first boss 23 away from the first ohmic contact structure 21.

The first boss 23 includes a sidewall 230. An included angle θ between the sidewall 230 and a plane where the substrate 10 is located ranges from 45 degrees and 90 degrees.

The first ohmic contact structure 21 includes a first sidewall 210. The first sidewall 210 is adjacent to the sidewall 230. The second ohmic contact structure 22 includes a second sidewall 220. The second sidewall 220 is adjacent to the sidewall 230. The included angles between the first sidewall 210 and the second sidewall 220 and the plane where the substrate is located may be equal to the included angle θ between the sidewall 230 and the plane where the substrate 10 is located. That is, the first sidewall 210 is on the same inclined plane as the sidewall 230 and the second sidewall 220.

In the embodiments of the present disclosure, materials of the first ohmic contact layer and the second ohmic contact layer are both N-type heavily doped amorphous silicon materials. Both the first ohmic contact layer and the second ohmic contact layer may be doped with impurity elements such as phosphorus or arsenic.

Material of the insulating layer may be a common inorganic insulating material such as silicon nitride, silicon oxide, or silicon oxynitride.

In the step S20, the first ohmic contact layer, the insulating layer, and the second ohmic contact layer may be sequentially deposited by means of chemical vapor deposition (CVD).

Step S3: the first ohmic contact structure 21, the first boss 23, and the second ohmic contact structure 22 are etched, so that the second ohmic contact structure 22 and the first boss 23 are partially etched, and the first ohmic contact structure 21 is not etched.

As shown in FIG. 13c, by partially etching the second ohmic contact structure 22 and the first boss 23, a portion of the first ohmic contact structure 21 is not covered by the first boss 23 and the second ohmic contact structure 22.

Step S4: an amorphous silicon layer is formed on the buffer layer 11, the amorphous silicon layer covers the first ohmic contact structure 21, the first boss 23, and the second ohmic contact structure 22; the amorphous silicon layer is subjected to a crystallization process, and then a semiconductor structure 24 is formed by patterning;
In the step S4, the amorphous silicon layer can be subjected to the crystallization process by an excimer laser annealing process, so that the amorphous silicon in the amorphous silicon layer can be transformed into a polycrystalline silicon structure. The polysilicon structure is then etched to form the semiconductor structure 24.

Energy of the excimer laser annealing process is limited and all absorbed by the amorphous silicon layer. When the amorphous silicon layer is crystallized, the first ohmic contact structure 21 and the second ohmic contact structure 22 can still keep in the amorphous silicon structure.

In the process of crystallizing the amorphous silicon layer, a seed crystal may be formed on the amorphous silicon layer at the corner of the buffer layer 11 and the sidewall 230 of the first boss 23. The seed crystal may grow along the direction of the sidewall 230. By controlling a length of the sidewall 230 to be between 0.01 micrometers and 1 micrometer, only one crystal grain can exist in the semiconductor structure 24 on the sidewall 230.

Step S5: a gate insulating layer 13 is formed on the semiconductor structure 24, the gate insulating layer 13 covers the semiconductor structure 24, the first ohmic contact structure 21, the first boss 23, and the second ohmic contact structure 22; a gate 25 is formed on the gate insulating layer 13;
Step S6: an interlayer dielectric layer 14 is formed on the gate insulating layer 13, the interlayer dielectric layer 14 covers the gate 25; a first via hole OH1 and a second via hole OH2 are formed on the interlayer dielectric layer 14, the first via hole OH1 exposes the first ohmic contact structure 21, and the second via hole OH2 exposes the second ohmic contact structure 22;
Step S7: a source 26 and a drain 27 are formed on the interlayer dielectric layer 14, the drain 27 is in contact with the first ohmic contact structure 21 through the first via hole OH1, and the source 26 is in contact with the second ohmic contact structure 22 through the second via OH2.

It should be noted that the manufacturing method of the display panel provided by the embodiments of the present disclosure only takes the structure of the first display panel shown in FIG. 1 to FIG. 3 as an example. For the manufacturing method of the display panel in other embodiments, reference may be made to the manufacturing method of the display panel shown in FIGS. 13a to 13b, which will not be repeated here.

Advantages of the embodiments of the present disclosure are as follows. Embodiments of the present disclosure provide the display panel. The display panel includes the substrate and includes the first ohmic contact structure, the first boss, the second ohmic contact structure, the semiconductor structure, and the gate which are stacked on the substrate. The first boss includes at least one sidewall. The semiconductor structure is disposed on the sidewall of the first boss, and is in contact with the first ohmic contact structure and the second ohmic contact structure. The channel length of the semiconductor structure can be shortened by using the existing technology, and the dimension of the thin film transistor can be reduced, so that an integration level of the thin film transistor in the display panel can be improved.

In summary, although the present disclosure is disclosed above with preferred embodiments, the above preferred embodiments are not intended to limit the present disclosure. Various changes and modifications can be made by those of ordinary skill in the art without departing from the spirit and scope of the present disclosure. Therefore, the protection scope of the present disclosure is based on the scope defined by the claims.

What is claimed is:

1. A display panel, comprising:
a substrate;
a first ohmic contact structure disposed on the substrate;
a first boss disposed on a side of the first ohmic contact structure away from the substrate, wherein the first boss comprises at least one sidewall;
a second ohmic contact structure disposed on a side of the first boss away from the first ohmic contact structure;
a semiconductor structure disposed at least on the sidewall and in contact with the first ohmic contact structure and the second ohmic contact structure; and
a gate disposed on a side of the semiconductor structure away from the substrate.

2. The display panel according to of claim 1, wherein the first ohmic contact structure comprises a first sidewall adjacent to the sidewall, and the semiconductor structure is in contact with the first sidewall.

3. The display panel according to claim 1, wherein the first ohmic contact structure comprises:
a body section disposed between the first boss and the substrate; and
a protruding section connected to the body section, wherein an orthographic projection of the protruding section on the substrate does not overlap with an orthographic projection of the first boss on the substrate, and the semiconductor structure is in contact with a surface of the protruding section away from the substrate.

4. The display panel according to claim 3, wherein a length of the protruding section ranges from 0.5 micrometers to 3 micrometers.

5. The display panel according to claim 1, wherein the semiconductor structure comprises:
a first section disposed on the substrate and/or the first ohmic contact structure;
a second section disposed on the sidewall and connected to the first section; and
a third section disposed on a side of the second ohmic contact structure away from the first boss, and connected to the second section.

6. The display panel according to claim 1, wherein an included angle between the sidewall and a plane where the substrate is located ranges from 45 degrees to 90 degrees.

7. The display panel according to claim 1, wherein the first boss comprises two sidewalls disposed opposite to each other, and the semiconductor structure and the gate disposed on the side of the semiconductor structure away from the substrate are arranged on the two sidewalls; and
wherein the semiconductor structure on the two sidewalls is in contact with the first ohmic contact structure and the second ohmic contact structure.

8. The display panel according to claim 7, wherein the semiconductor structure is continuously disposed on the two sidewalls of the first boss and the second ohmic contact structure.

9. The display panel according to claim 8, wherein an orthographic projection of the gate on the substrate covers an orthographic projection of the semiconductor structure on the substrate.

10. The display panel according to claim 1, wherein the display panel comprises:
a third ohmic contact structure disposed on the substrate;
a second boss disposed on a side of the third ohmic contact structure away from the substrate; and
a fourth ohmic contact structure disposed on a side of the second boss away from the first ohmic contact structure, wherein the semiconductor structure is arranged at least on a sidewall of the second boss, and is in contact with the third ohmic contact structure and the fourth ohmic contact structure;
wherein the display panel further comprises a source and a drain, one of the source and the drain is electrically connected to the first ohmic contact structure and the third ohmic contact structure, and another one of the source and the drain is electrically connected to the second ohmic contact structure and the fourth ohmic contact structure.

11. The display panel according to claim 10, wherein the semiconductor structure is continuously disposed on the first boss, the second boss, and a region between the first boss and the second boss.

12. The display panel according to claim 11, wherein an orthographic projection of the gate on the substrate covers an orthographic projection of the semiconductor structure on the substrate.

13. The display panel according to claim 1, wherein the display panel further comprises a gate insulating layer and an interlayer dielectric layer, the gate insulating layer is disposed at least between the gate and the semiconductor structure and covers the second ohmic contact structure and the first ohmic contact structure, the interlayer dielectric layer is disposed on a side of the gate insulating layer away from the substrate and covers the gate;
the display panel further comprises a source and a drain, the source and the drain are both disposed on a side of the interlayer dielectric layer away from the substrate, one of the source and the drain is in contact with the first ohmic contact structure through the interlayer dielectric layer and the gate insulating layer, and another one of the source and the drain is in contact with the second ohmic contact structure through the interlayer dielectric layer and the gate insulating layer.

14. The display panel according to claim 1, wherein the display panel further comprises a light-shielding structure, the light-shielding structure is disposed on a side of the first ohmic contact structure close to the substrate, and the semiconductor structure comprises a channel portion connected to the first ohmic contact structure and the second ohmic contact structure;
wherein an orthographic projection of the light-shielding structure on the substrate covers an orthographic projection of the channel portion on the substrate.

15. The display panel according to claim 14, wherein a length of the channel portion along an extending direction of the sidewall ranges from 0.01 micrometer to 1 micrometer.

16. The display panel according to claim 1, wherein a thickness of the first boss in a thickness direction of the display panel ranges from 0.0071 micrometers to 1 micrometer.

17. The display panel according to claim 1, wherein the first boss is a single-layer or multi-layer structure.

18. The display panel according to claim 1, wherein material of the first boss comprises one or a combination of silicon nitride, silicon oxide, and silicon oxynitride.

19. The display panel according to claim 1, wherein material of the first boss comprises one or a combination of acrylic based resin, epoxy resin, phenolic resin, polyamide based resin, polyimide based resin, unsaturated polyester resin, polyacrylate, polycarbonate, polyimide, polystyrene.

20. The display panel according to claim 1, wherein the sidewall comprises a flat surface or an arc surface.
